(19) United States
(12) Patent Application Publication
(10) Pub. No.: US 2024/0421559 A1
(43) Pub. Date: Dec. 19, 2024

(54) SEMICONDUCTOR LASER

(71) Applicant: Mitsubishi Electric Corporation, Tokyo (JP)

(72) Inventor: Yuki TAKETOMI, Tokyo (JP)

(73) Assignee: Mitsubishi Electric Corporation, Tokyo (JP)

(21) Appl. No.: 18/701,477

(22) PCT Filed: Mar. 15, 2022
(86) PCT No.: PCT/JP2022/011706

§ 371 Date: Apr. 15, 2024

(51) Int. Cl. H01S 5/028; H01S 5/042; H01S 5/22

(52) U.S. Cl. CPC H01S 5/0282; H01S 5/04252; H01S 5/2206

(57) ABSTRACT

A compound semiconductor multilayer (2-4) is film formed on a compound semiconductor substrate (1) and includes a ridged stripe (5) and a resonator end face (6) which corresponds to a cleavage plane perpendicular to a long-side direction of the stripe (5). A first Au electrode (8) is formed on the stripe (5) in a region of up to the resonator end face (6). A second Au electrode (9) is formed on the first Au electrode (8) in a region excluding a region adjacent to the resonator end face (6). A metal layer (10) made of metal harder than Au is formed on the first Au electrode (8) in the region adjacent to the resonator end face (6). A coating film (12) is formed on the resonator end face (6).

### FIELD

The present disclosure relates to a semiconductor laser in which a coating film is formed on a resonator end face corresponding to a cleavage plane.

### BACKGROUND ART

In a compound semiconductor laser, a compound semiconductor multilayer film, which corresponds to a laser structure, has ridged stripes formed thereon. An electrode for passing a current through the laser is formed on the stripes. The compound semiconductor multilayer film is cleaved in a direction perpendicular to the long-side direction of the stripes so that a resonator end face is formed. A coating film is formed to protect the resonator end face and obtain desired reflectivity of the end face.

The electrode on the stripes also serves a role of prolonging the life of the laser by radiating heat generated within the laser to the outside through a pad electrode formed on the electrode. Thus, an Au electrode with high thermal conductivity is used as the electrode. Forming an Au electrode on the stripes in a region of up to the resonator end face is effective in enhancing the heat radiation characteristics of the laser and thus producing a highly reliable laser element. However, when an Au electrode is formed in a region of up to the resonator end face, it would be necessary to perform cleavage at the position where the Au electrode is formed on the stripes. Since Au has high ductility, when the compound semiconductor is attempted to be cleaved together with the Au electrode, the Au electrode would be torn off while being pulled as it is divided into two segments, and then would hang down over the resonator end face.

When the coating film is formed thereafter, a cavity is generated between the coating film and the resonator end face due to the obstructive hanging portion of Au. If moisture enters via the cavity, the characteristics of the laser would change. When a multilayer film is used as the coating film, it is possible to enhance the moisture resistance of the entire coating film by using a film with high moisture resistance as the top layer of the multilayer film. However, if a cavity such as the one described above is present, moisture in the atmosphere would directly permeate an inner layer, which has lower moisture resistance than that of the top layer, of the coating film via the cavity. This leads to significantly degraded moisture resistance of the laser.

In contrast, there is disclosed a technology for improving cleavability by reducing the thickness of an Au electrode at a cleavage position as compared to the thickness of the other portions (for example, see PTL 1).

### CITATION LIST

### Patent Literature

[PTL 1] JP 2000-22272 A

### SUMMARY OF THE INVENTION

### Problem to be Solved by the Invention

However, it would be impossible to sufficiently suppress the hanging of Au over a resonator end face only by reducing the thickness of the Au electrode at the cleavage position. Thus, moisture would permeate via the cavity generated due to the handing of Au, resulting in degraded moisture resistance of the laser.

The present disclosure has been made to solve the foregoing problem, and it is an object of the present disclosure to sufficiently suppress the handing of Au over a resonator end face, and thus obtain a semiconductor laser with moisture resistance that would hardly degrade.

### Solution to Problem

A semiconductor laser according to the present disclosure includes: a compound semiconductor substrate; a compound semiconductor multilayer film formed on the compound semiconductor substrate and including a ridged stripe and a resonator end face which corresponds to a cleavage plane perpendicular to a long-side direction of the stripe; a first Au electrode formed on the stripe in a region of up to the resonator end face; a second Au electrode formed on the first Au electrode in a region excluding a region adjacent to the resonator end face; a metal layer formed on the first Au electrode in the region adjacent to the resonator end face and made of metal harder than Au; and a coating film formed on the resonator end face.

### Advantageous Effects of Invention

In the present disclosure, the second Au electrode is not formed in the region adjacent to the resonator end face, and instead, the metal layer that is harder than Au is formed therein. This can sufficiently suppress the handing of Au over the resonator end face when cleavage is performed. Thus, since the generation of the cavity due to the handing of Au can be prevented, degradation in the moisture resistance can be prevented.

### BRIEF DESCRIPTION OF THE DRAWINGS

FIG. 1 is a perspective view illustrating a semiconductor laser according to Embodiment 1.

FIG. 2 is a cross-sectional view illustrating the semiconductor laser according to embodiment 1.

FIG. 3 is a cross-sectional view illustrating the steps of producing the semiconductor laser according to Embodiment 1.

FIG. 4 is a cross-sectional view illustrating the steps of producing the semiconductor laser according to Embodiment 1.

FIG. 5 is a cross-sectional view illustrating the steps of producing the semiconductor laser according to Embodiment 1.

FIG. 6 is a cross-sectional view illustrating the steps of producing the semiconductor laser according to Embodiment 1.

FIG. 7 is a cross-sectional view illustrating the steps of producing a semiconductor laser according to the comparative example.

FIG. 8 is a cross-sectional view illustrating the steps of producing a semiconductor laser according to the comparative example.

FIG. 9 is a cross-sectional view illustrating the steps of producing a semiconductor laser according to the comparative example.

FIG. 10 is a partially enlarged cross-sectional view of a semiconductor laser according to Embodiment 2.

### DESCRIPTION OF EMBODIMENTS

A semiconductor laser according to the embodiments of the present disclosure will be described with reference to the drawings. The same components will be denoted by the same symbols, and the repeated description thereof may be omitted.

### Embodiment 1

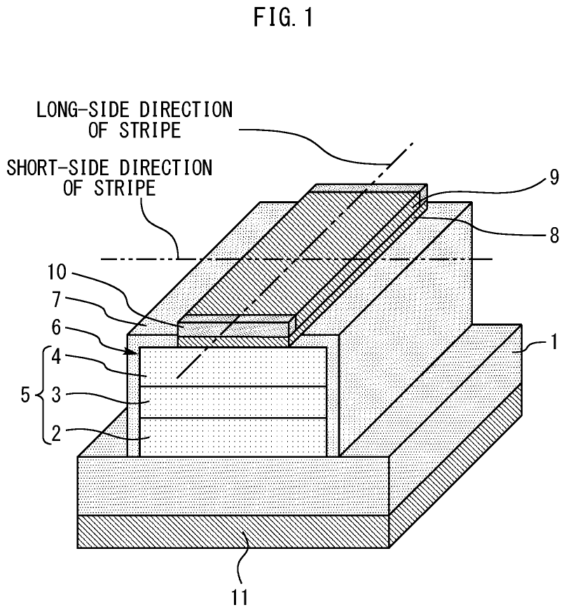

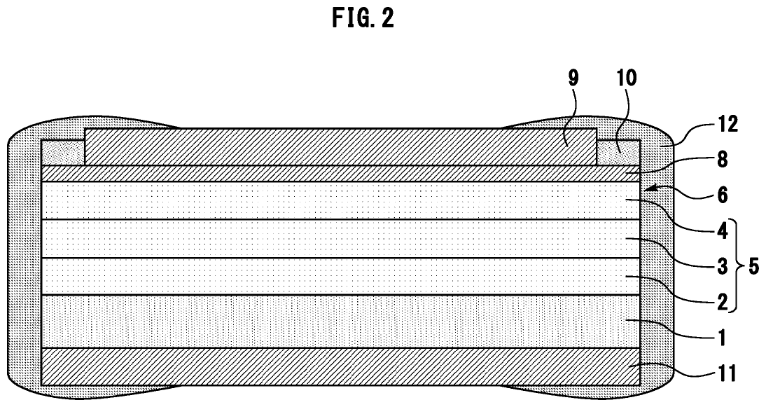

FIG. 1 is a perspective view illustrating a semiconductor laser according to Embodiment 1. FIG. 2 is a cross-sectional view illustrating the semiconductor laser according to Embodiment 1. A compound semiconductor substrate 1 is an n-InP substrate, for example. An n-InP clad layer 2, an active layer 3, and a p-InP clad layer 4 are formed in this order as a compound semiconductor multilayer film to become a laser oscillator on the compound semiconductor substrate 1. The compound semiconductor multilayer film has ridged stripes 5 and a resonator end face 6 formed thereon. The resonator end face 6 corresponds to a cleavage plane perpendicular to the long-side direction of the stripes 5. Note that FIG. 2 is a cross-sectional view along the long-side direction of the stripes 5. The side surfaces and the upper surfaces of the stripes 5 perpendicular to the short-side direction of the stripes 5 are partially covered with an insulating protective film 7.

A first Au electrode 8 is formed on the upper surfaces of the stripes 5 exposed from an opening of the insulating protective film 7 in a region of up to the resonator end face 6. That is, the first Au electrode 8 is also formed in a region adjacent to the resonator end face 6. A second Au electrode 9 is formed on the first Au electrode 8 in a region excluding the region adjacent to the resonator end face 6. A metal layer 10 is formed on the first Au electrode 8 in the region adjacent to the resonator end face 6. The metal layer 10 is made of metal harder than Au. For example, the metal layer 10 is made of Ti, Ni, or Cr.

The lower surface of the compound semiconductor substrate 1 has a lower-surface electrode 11 formed thereon. A coating film 12 is formed on the resonator end face 6. The coating film 12 is a single-layer insulating film, but may also be a multilayer film. The coating film 12 is formed on each of the front end face and the rear end face of the semiconductor laser. Note that the coating film 12 is omitted in FIG. 1.

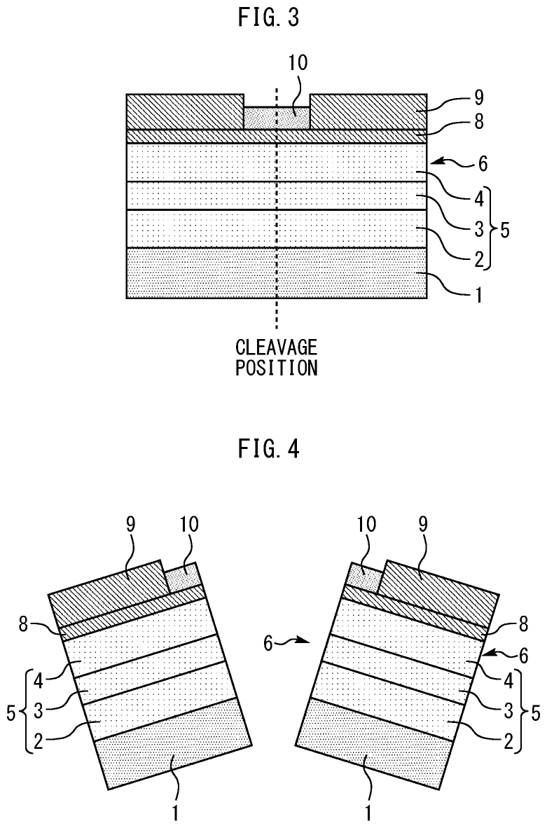

FIGS. 3 to 6 are cross-sectional views illustrating the steps of producing the semiconductor laser according to Embodiment 1. First, as illustrated in FIG. 3, the n-InP clad layer 2, the active layer 3, and the p-InP clad layer 4 are formed in this order as a compound semiconductor multilayer film on the compound semiconductor substrate 1. A striped mask layer is formed on the compound semiconductor multilayer film, and portions not covered with the mask layer are etched so that the ridged stripes 5 are formed on the compound semiconductor multilayer film. After the mask layer is removed, the insulating protective film 7 is formed so as to cover the upper surfaces and the side surfaces of the stripes 5. The insulating protective film 7 on the upper surfaces of the stripes 5 is etched so that an opening is formed. The first Au electrode 8 is formed in the opening through vapor deposition, for example. Next, the second Au electrode 9 is formed on the first Au electrode 8 at a position excluding a cleavage position as well as a region adjacent thereto. Accordingly, the Au electrode is formed in a stripe pattern such that it is thin only at the cleavage position as well as the region adjacent thereto. Next, the metal layer 10 is formed on the first Au electrode 8 at the cleavage position as well as the region adjacent thereto. After that, the lower-surface electrode 11 is formed on the lower surface of the compound semiconductor substrate 1. Note that the lower-surface electrode 11 is omitted in FIGS. 3 to 6.

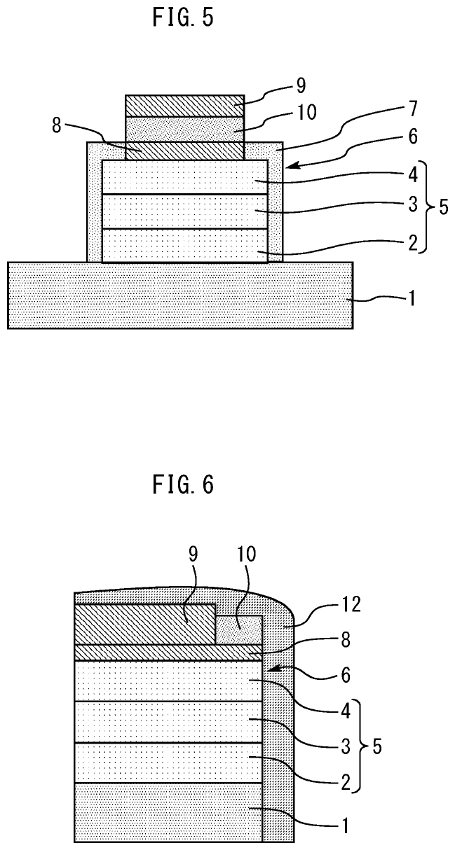

Next, as illustrated in FIG. 4, the compound semiconductor substrate 1 and the compound semiconductor multilayer film are cleaved together with the first Au electrode 8 and the metal layer 10 in a direction toward the side of the compound semiconductor substrate 1 from the side of the metal layer 10. FIG. 5 illustrates the resonator end face 6 formed through the cleavage. Next, as illustrated in FIG. 6, the coating film 12 is formed on the resonator end face 6 through vapor deposition or sputtering, for example.

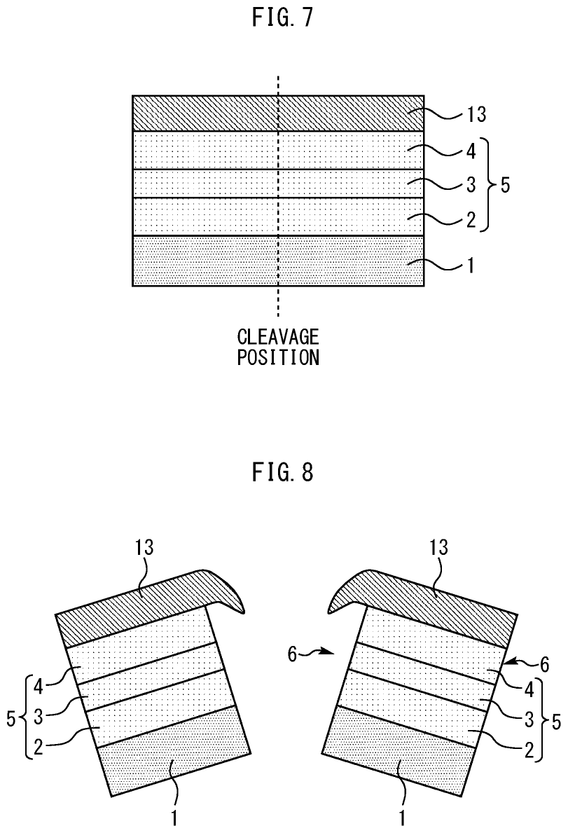

Next, the advantageous effects of this embodiment will be described in comparison with a comparative example. FIGS. 7 to 9 are cross-sectional views illustrating the steps of producing a semiconductor laser according to the comparative example. In the comparative example, as illustrated in FIG. 7, only an Au electrode 13 is formed on the stripes 5. Next, as illustrated in FIG. 8, the compound semiconductor substrate 1 and a compound semiconductor multilayer film are cleaved together with the Au electrode 13 from the side of the Au electrode 13. Since Au has high ductility, the Au electrode 13 is torn off while being pulled, and then hangs down over the resonator end face 6.

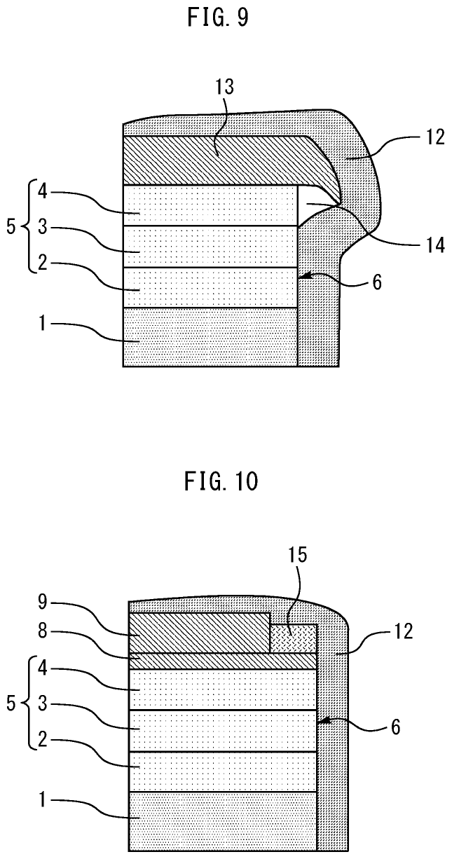

Next, as illustrated in FIG. 9, a coating film is formed on the resonator end face 6. At this time, a cavity 14 is generated between the coating film 12 and the resonator end face 6 due to the obstructive hanging portion of Au. Thus, moisture enters via the cavity 14, which in turn degrades the moisture resistance of the laser. Note that it would be impossible to sufficiently suppress the hanging of Au over the resonator end face 6 only by reducing the thickness of the Au electrode 13 at the cleavage position.

In contrast, in this embodiment, the second Au electrode 9 is not formed in the region adjacent to the resonator end face 6, and instead, the metal layer 10 that is harder than Au is formed therein. This can sufficiently suppress the handing of Au over the resonator end face 6 when cleavage is performed. Thus, since the generation of the cavity 14 due to the handing of Au can be prevented, degradation in the moisture resistance can be prevented.

In addition, since the first Au electrode 8 is formed on the upper surfaces of the stripes 5 in a region of up to the resonator end face 6, heat generated at the laser end face is radiated through the first Au electrode 8. Note that the metal layer 10 also serves advantageously in radiating heat.

The length from the resonator end face 6 to the second Au electrode 9 in the long-side direction of the stripes 5 is preferably 10 μm to 100 μm. If the length is smaller than 10 μm that is roughly the accuracy of the cleavage position, it would be difficult to perform cleavage at the thin region of the Au electrode. Meanwhile, if the length is greater than 100 μm, it would be difficult to ensure heat radiation characteristics in the region adjacent to the resonator end face 6.

Further, if the first Au electrode 8 is too thin, it would be difficult to control the thickness of the first Au electrode 8 when it is formed through vapor deposition, for example. Thus, the thickness of the first Au electrode 8 is preferably 300 Å to 1000 Å. The thickness of the second Au electrode 9 is 1 to 3 μm. The thickness of the metal layer 10 is 300 Å to 2000 Å.

### Embodiment 2

FIG. 10 is a partially enlarged cross-sectional view of a semiconductor laser according to Embodiment 2. Instead of the metal layer 10 in Embodiment 1, an insulating film 15 is formed on the first Au electrode 8 in the region adjacent to the resonator end face 6. The insulating film 15 and the coating film 12 are formed of different materials. The insulating film 15 is an SiO₂ film, for example. Since the insulating film 15 with higher cleavability than that of metal is provided on the first Au electrode 8 at the cleavage position, it is possible to sufficiently suppress the hanging of Au over the resonator end face 6 when cleavage is performed. The other configurations and advantageous effects are similar to those of Embodiment 1.

Note that the present disclosure is not limited to the foregoing embodiments, and can be modified in various ways within the gist of the present disclosure. In addition, the present disclosure includes all possible combinations of the configurations illustrated in the foregoing embodiments.

### REFERENCE SIGNS LIST

1 compound semiconductor substrate; 2 n-InP clad layer (compound semiconductor multilayer film); 3 active layer (compound semiconductor multilayer film); 4 p-InP clad layer (compound semiconductor multilayer film); 5 stripe; 6 resonator end face; 8 first Au electrode; 9 second Au electrode: 10 metal layer; 12 coating film; 15 insulating film

1. A semiconductor laser comprising:
a compound semiconductor substrate;
a compound semiconductor multilayer film formed on the compound semiconductor substrate and including a ridged stripe and a resonator end face which corresponds to a cleavage plane perpendicular to a long-side direction of the stripe;
a first Au electrode formed on the stripe in a region of up to the resonator end face;
a second Au electrode formed on the first Au electrode in a region excluding a region adjacent to the resonator end face;
a metal layer formed on the first Au electrode in the region adjacent to the resonator end face and made of metal harder than Au; and
a coating film formed on the resonator end face.

2. The semiconductor laser according to claim 1, wherein the metal layer is made of Ti, Ni, or Cr.

3. A semiconductor laser comprising:
a compound semiconductor substrate;
a compound semiconductor multilayer film formed on the compound semiconductor substrate and including a ridged stripe and a resonator end face which corresponds to a cleavage plane perpendicular to a long-side direction of the stripe;
a first Au electrode formed on the stripe in a region of up to the resonator end face;
a second Au electrode formed on the first Au electrode in a region excluding a region adjacent to the resonator end face;
an insulating film formed on the first Au electrode in the region adjacent to the resonator end face; and
a coating film formed on the resonator end face and formed of a material different from that of the insulating film.

4. The semiconductor laser according to claim 1, wherein a length from the resonator end face to the second Au electrode in a long-side direction of the stripe is 10 μm to 100 μm.

5. The semiconductor laser according to claim 2, wherein a length from the resonator end face to the second Au electrode in a long-side direction of the stripe is 10 μm to 100 μm.

6. The semiconductor laser according to claim 3, wherein a length from the resonator end face to the second Au electrode in a long-side direction of the stripe is 10 μm to 100 μm.
